(19) United States
(12) Patent Application Publication
(10) Pub. No.: US 2023/0326406 A1
(43) Pub. Date: Oct. 12, 2023

(54) DISPLAY DEVICE WITH PIXEL SELECTOR

(71) Applicant: SAMSUNG DISPLAY CO., LTD., YONGIN-SI (KR)

(72) Inventors: BYUNGSUN KIM, YONGIN-SI (KR); SANGWON SEOK, YONGIN-SI (KR)

(21) Appl. No.: 18/159,459

(22) Filed: Jan. 25, 2023

(30) Foreign Application Priority Data
Apr. 12, 2022 (KR) 10-2022-0045155

(51) Int. Cl. G09G 3/3233; H10K 59/131; G09G 3/20

(52) U.S. Cl. CPC G09G 3/3233; H10K 59/131; G09G 3/2096; G09G 2300/0819; G09G 2300/0842; G09G 2300/0861; G09G 2310/08

(57) ABSTRACT

A display device includes a first pixel, a second pixel adjacent to the first pixel, a selection circuit disposed between the first pixel and the second pixel, and a data line connected to the selection circuit, wherein the selection circuit selectively connects the data line to the first pixel and the second pixel.

### CROSS-REFERENCE TO RELATED APPLICATION

This U.S. non-provisional patent application claims priority under 35 U.S.C. § 119 to Korean Patent Application No. 10-2022-0045155, filed on Apr. 12, 2022, the entire disclosure of which is hereby incorporated by reference.

### FIELD

The present disclosure relates to display devices, and more particularly relates to a display device with pixel selector.

### DISCUSSION

An electronic device, such as a smartphone, a digital camera, a laptop computer, a navigational device, a smart TV, or the like which provides an image to a user, generally includes a display device for displaying the image. The display device generates the image and provides the generated image to the user through a display screen.

The display device includes a display panel having a plurality of pixels for generating an image, and a data driver for driving the pixels. The data driver provides data voltages to the pixels, and the pixels generate light corresponding to the data voltages. The data voltages are provided to the pixels through data lines connected to the pixels.

The data driver may be disposed on a flexible circuit board, and the data lines may be connected to a plurality of pads disposed on the display panel. The data driver may be connected to the pads through the flexible circuit board. As a resolution of a display panel increases, the number of pixels generally increases. Embodiments of the present disclosure may be capable of reducing the number of data lines for a given number of pixels and/or increasing the number of pixels for a given number of data lines.

### SUMMARY

Embodiments of the present disclosure may provide display devices capable of reducing the number of data lines and the surface area of a fan-out portion for a given number of pixels or resolution, or increasing the number of pixels or resolution for a given number of data lines and surface area of the fan-out portion.

An embodiment of the present disclosure provides a display device including: a first pixel; a second pixel adjacent to the first pixel; a selection circuit disposed between the first pixel and the second pixel; and a data line connected to the selection circuit, wherein the selection circuit selectively connects the data line to at least one of the first pixel and the second pixel.

In an embodiment, the selection circuit may alternately connect the data line to one of the first pixel and the second pixel and then to the other of the first pixel and the second pixel.

In an embodiment, the first pixel and the second pixel may have structures symmetric to each other.

In an embodiment, the selection circuit may include: a first switching element configured to switch a connection between the data line and the first pixel; and a second switching element configured to switch a connection between the data line and the second pixel.

In an embodiment, the data line may be disposed between the first switching element and the second switching element to be connected to the first switching element and the second switching element.

In an embodiment, the first switching element may be disposed between the data line and the first pixel to be connected to the data line and the first pixel.

In an embodiment, the second switching element may be disposed between the data line and the second pixel to be connected to the data line and the second pixel.

In an embodiment, the first and second switching elements may include PMOS transistors.

In an embodiment, the display device may further include: a first selection line connected to the first switching element and configured to receive a first switching control signal to control on/off states of the first switching element; and a second selection line connected to the second switching element and configured to receive a second switching control signal to control on/off states of the second switching element.

In an embodiment, the data line, the first selection line, and the second selection line may extend in the same direction.

In an embodiment, the first switching control signal may be an inverted signal of the second switching control signal.

In an embodiment, the first switching element may include: a first electrode connected to the data line; a second electrode connected to the first pixel; and a control electrode connected to the first selection line.

In an embodiment, the second switching element may include: a first electrode connected to the data line; a second electrode connected to the second pixel; and a control electrode connected to the second selection line.

In an embodiment, the display device may further include: a timing controller configured to generate the first and second switching control signals; a first signal line connected to the timing controller to output the first switching control signal; and a second signal line connected to the timing controller to output the second switching control signal.

In an embodiment, each of the first and second pixels, the data line, the first selection line, and the second selection line may be provided in plurality, wherein the plurality of first selection lines are connected in common to the first signal line.

In an embodiment, the plurality of second selection lines may be connected in common to the second signal line.

In an embodiment of the present disclosure, a display device includes: a first pixel; a second pixel adjacent to the first pixel; a data line disposed between the first pixel and the second pixel and configured to be connected to the first pixel and the second pixel; a first switching element disposed between the first pixel and the data line and configured to be connected to the first pixel and the data line; and a second switching element disposed between the second pixel and the data line and configured to be connected to the second pixel and the data line, wherein the first switching element and the second switching element are alternately turned on.

### BRIEF DESCRIPTION OF THE DRAWINGS

The accompanying drawings are included to provide a further understanding of the present disclosure, and are incorporated in and constitute a part of the present disclosure. The drawings illustrate embodiments of the present disclosure and, together with the description, serve to describe principles of the present disclosure. In the drawings:

FIG. 1 is a perspective view diagram of a display device according to an embodiment of the present disclosure;

FIG. 2 is a cross-sectional diagram that illustrates, as an example, a cross section of the display device illustrated in FIG. 1;

FIG. 3 is a cross-sectional diagram that illustrates, as an example, a cross section of the display panel illustrated in FIG. 2;

FIG. 4 is a block diagram of the display device illustrated in FIG. 1;

FIG. 5 is a plan view diagram of the display device with display panel illustrated in FIG. 4;

FIG. 6 is a circuit diagram that illustrates, as an example, an equivalent circuit of any one of the second pixels illustrated in FIG. 5;

FIG. 7 is a circuit diagram that illustrates, as an example, equivalent circuits of one of the first pixels and one of the second pixels adjacent to each other and a corresponding one of the selection circuits illustrated in FIG. 5;

FIG. 8 is a timing diagram of first and second switching control signals applied to the first and second switching elements illustrated in FIG. 7; and

FIG. 9 is a plan view diagram of a display device with display panel according to an embodiment of the present disclosure.

### DETAILED DESCRIPTION

In the description by way of example that follows, it shall be understood that when an element or layer is referred to as being “on”, “connected to”, or “coupled to” another element or layer, it can be directly on, connected to, or coupled to the other element or layer, or intervening elements or layers may be present.

Like reference numerals may refer to like elements throughout the present disclosure. In the figures, the thicknesses, ratios, and dimensions of elements may be exaggerated for effective description of the technical contents.

As used herein, the term “and/or” includes any and all combinations of one or more of the associated listed items.

It shall be understood that, although the terms first, second, or the like may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of the present disclosure. As used herein, the singular forms, “a”, “an”, and “the” are intended to include the plural forms as well, unless the context clearly indicates otherwise.

Spatially relative terms, such as “beneath”, “below”, “lower”, “above”, and “upper”, may be used herein for ease of description to describe one element or feature's relationship to another element(s) or feature(s) as illustrated in the figures. It shall be understood that the spatially relative terms are intended to encompass different orientations of the device in use or operation in addition to the orientation depicted in the figures.

Unless otherwise defined, all terms used herein, including technical and scientific terms, have the same meaning as commonly understood by one of ordinary skill in the art to which the present disclosure pertains. It shall be further understood that terms, such as those defined in commonly used dictionaries, should be interpreted as having meanings that are consistent with their meanings in the context of the relevant art and shall not be interpreted in an idealized or overly formal sense unless expressly so defined herein.

It shall be further understood that the terms “include” or “have” or the like, when used in the present disclosure, specify the presence of stated features, integers, steps, operations, elements, components, and/or groups thereof, but do not preclude the presence or addition of one or more other features, integers, steps, operations, elements, components, and/or groups thereof.

Hereinafter, illustrative embodiments of the present disclosure will be explained by way of example in greater detail with reference to the accompanying drawings.

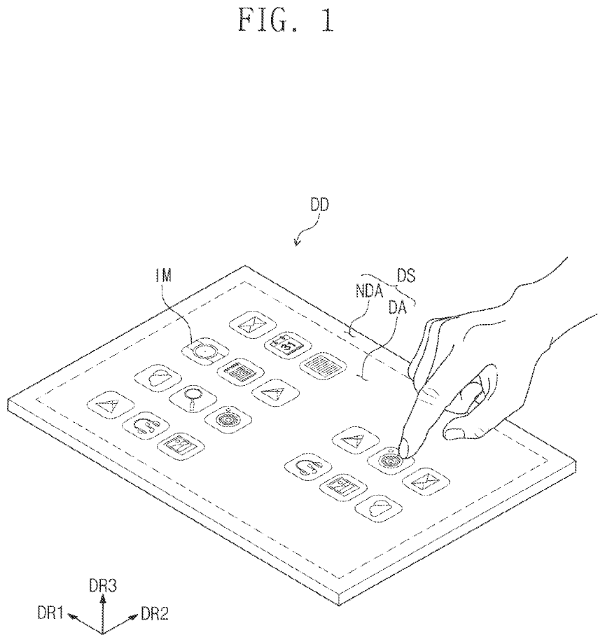

FIG. 1 illustrates a display device according to an embodiment of the present disclosure.

Referring to FIG. 1, a display device DD according to an embodiment of the present disclosure may have a rectangular shape having long sides extending in a first direction DR1 and short sides extending in a second direction DR2 crossing the first direction DR1. However, the display device DD is not limited thereto and may have various shapes such as a circular shape and/or a polygonal shape.

Hereinafter, a direction substantially perpendicular to a plane defined by the first direction DR1 and the second direction DR2 is defined as a third direction DR3. In addition, in the present disclosure, “when viewed on a plane” is defined as a state of being viewed from the third direction DR3.

A top surface of the display device DD may be defined as a display surface DS and may have a plane defined by the first direction DR1 and the second direction DR2. Images IM generated by the display device DD may be provided to a user through the display surface DS.

The display surface DS may include a display area DA and a non-display area NDA around the display area DA. The display area DA may display an image, and the non-display area NDA need not display an image. The non-display area NDA may surround the display area DA and define an edge of the display device DD printed in a predetermined color.

The display device DD may be used in large-sized electronic devices such as a television, a monitor, and an outdoor digital signage. In addition, the display device DD may be used in small- and medium-sized electronic devices such as a personal computer, a laptop computer, a personal digital assistant, a car navigation device, a game machine, a smartphone, a tablet, and a camera. However, these are merely presented as embodiments, and the display device DD may also be used in other electronic devices as long as the display device DD does not depart from the present disclosure.

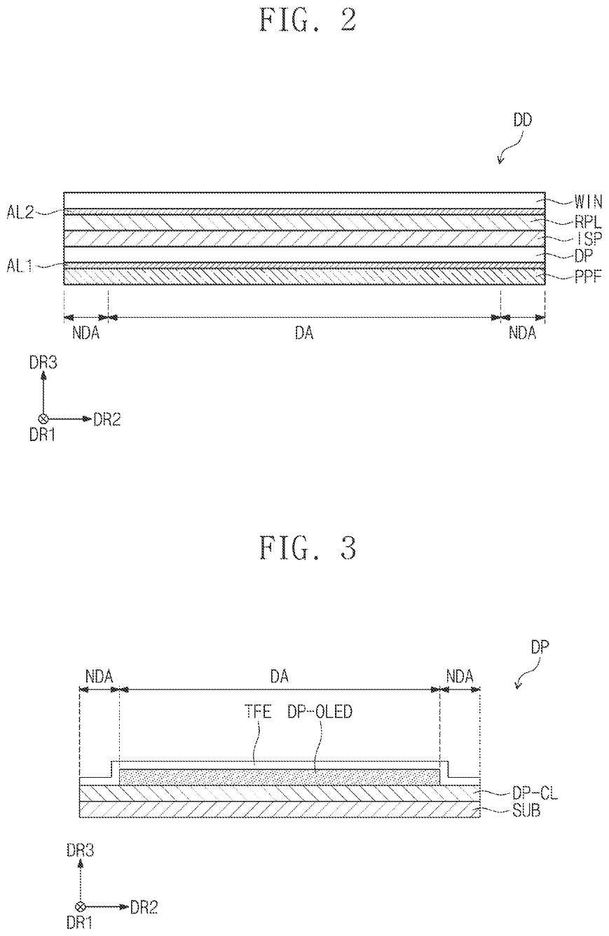

FIG. 2 illustrates, as an example, a cross section of the display device illustrated in FIG. 1.

As an example, a cross section of the display device DD viewed in the first direction DR1 is illustrated in FIG. 2.

Referring to FIG. 2, the display device DD may include a display panel DP, an input sensing unit ISP, an anti-reflection layer RPL, a window WIN, a panel protective film PPF, and first and second adhesive layers AL1 and AL2.

The display panel DP may be a flexible display panel. The display panel DP according to an embodiment of the present disclosure may be a light emitting display panel and is not particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include quantum dots, quantum rods, and the like. Hereinafter, the display panel DP is described as an organic light emitting display panel.

The input sensing unit ISP may be disposed on the display panel DP. The input sensing unit ISP may include a plurality of sensors (not illustrated) for sensing an external input in a capacitive manner. The input sensing unit ISP may be directly manufactured on the display panel DP when the display device DD is manufactured. However, the input sensing unit ISP is not limited thereto and may be manufactured as a panel separate from the display panel DP to be attached to the display panel DP by an adhesive layer.

The anti-reflection layer RPL may be disposed on the input sensing unit ISP. The anti-reflection layer RPL may be directly manufactured on the input sensing unit ISP when the display device DD is manufactured. However, the anti-reflection layer RPL is not limited thereto and may be manufactured as a separate panel to be attached to the input sensing unit ISP by an adhesive layer.

The anti-reflection layer RPL may be defined as a film that prevents reflection of external light. The anti-reflection layer RPL may reduce the degree of reflection of external light incident on the display panel DP from above the display device DD. External light need not be viewed by a user due to the anti-reflection layer RPL.

When external light traveling toward the display panel DP is reflected by the display panel DP to be provided again to an external user, the user may view the external light as when the user looks at a mirror. To prevent this phenomenon, the anti-reflection layer RPL may include, as an example, a plurality of color filters respectively displaying the same colors as pixels of the display panel DP.

The color filters may filter external light to colors respectively the same as those of the pixels. In this case, the external light need not be viewed by a user. However, the anti-reflection layer RPL is not limited thereto and may include a retarder and/or a polarizer to reduce the degree of reflection of external light.

The window WIN may be disposed on the anti-reflection layer RPL. The window WIN may protect the display panel DP, the input sensing unit ISP, and the anti-reflection layer RPL from external scratches and impacts.

The panel protective film PPF may be disposed on a lower portion of the display panel DP. The panel protective film PPF may protect the lower portion of the display panel DP. The panel protective film PPF may include a flexible plastic material such as polyethylene terephthalate (PET).

The first adhesive layer AL1 may be disposed between the display panel DP and the panel protective film PPF, and the display panel DP and the panel protective film PPF may be bonded to each other by the first adhesive layer AL1. The second adhesive layer AL2 may be disposed between the window WIN and the anti-reflection layer RPL, and the window WIN and the anti-reflection layer RPL may be bonded to each other by the second adhesive layer AL2.

FIG. 3 illustrates, as an example, a cross section of the display panel illustrated in FIG. 2.

As an example, a cross section of the display panel DP viewed in the first direction DR1 is illustrated in FIG. 3.

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA. The substrate SUB may include a flexible plastic material such as glass and polyimide (PI). The display element layer DP-OLED may be disposed on the display area DA.

The plurality of pixels may be disposed in the circuit element layer DP-CL and the display element layer DP-OLED. Each of the pixels may include transistors disposed in the circuit element layer DP-CL and a light emitting element disposed in the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and external foreign matter.

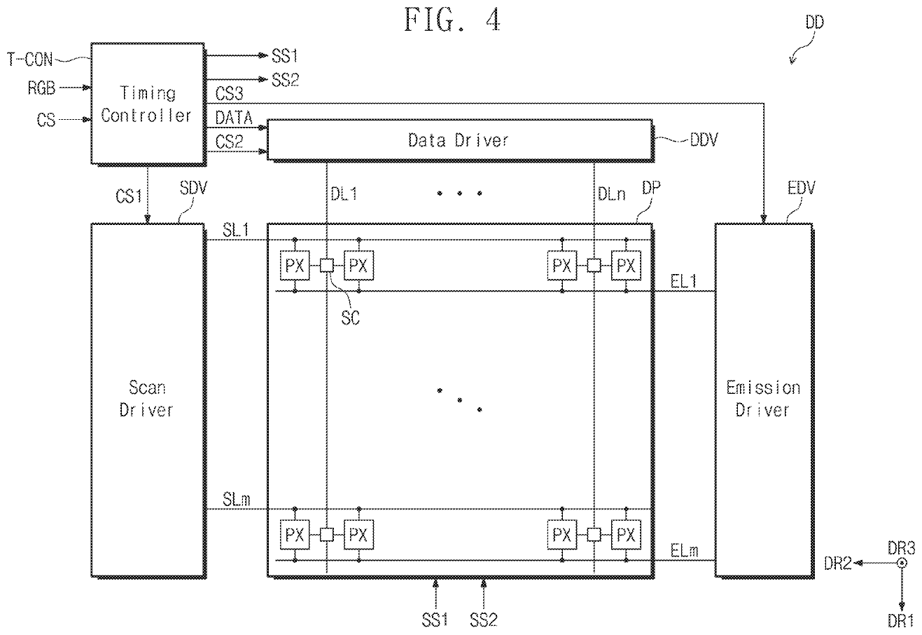

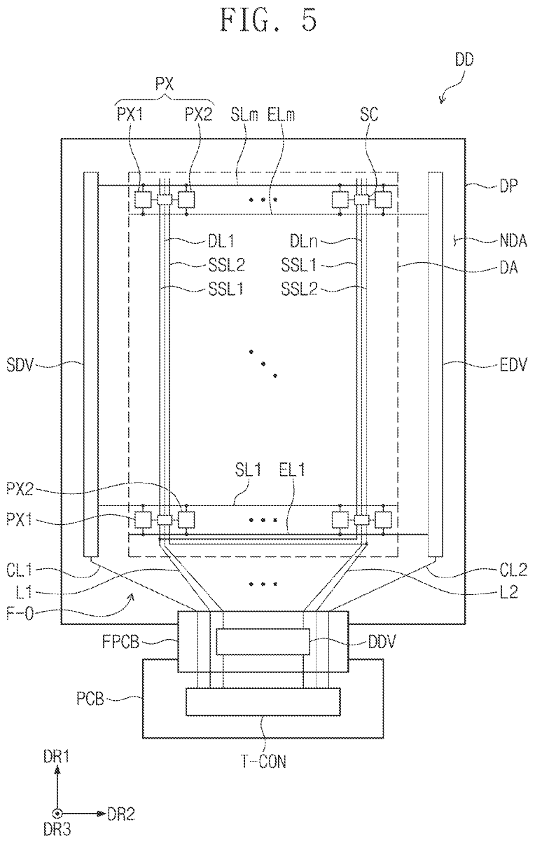

FIG. 4 is a block diagram of the display device illustrated in FIG. 1.

Referring to FIG. 4, the display device DD may include the display panel DP, a scan driver SDV, a data driver DDV, an emission driver EDV, and a timing controller T-CON.

The display panel DP may include a plurality of pixels PX, a plurality of selection circuits SC, a plurality of scan lines SL1 to SLm, a plurality of data lines DL1 to DLn, and a plurality of emission lines EL1 to ELm. Here, m and n are natural numbers.

The pixels PX may be arranged in the first direction DR1 and the second direction DR2. The pixels PX may be arranged in a matrix form, but the arrangement form of the pixels PX is not limited thereto.

The selection circuits SC may be disposed between odd-numbered pixels PX and even-numbered pixels PX to be connected to the odd-numbered pixels PX and the even-numbered pixels PX. For example, each of the selection circuits SC may be disposed between a pair of an odd-numbered pixel PX and a corresponding even-numbered pixel PX to be connected to the pair of the odd-numbered pixel PX and the even-numbered pixel PX.

The scan lines SL1 to SLm may extend in the second direction DR2 to be connected to the pixels PX and the scan driver SDV. The emission lines EL1 to ELm may extend in the second direction DR2 to be connected to the pixels PX and the emission driver EDV.

The data lines DL1 to DLn may extend in the first direction DR1 to be connected to the data driver DDV. The data lines DL1 to DLn may be connected to the selection circuits SC arranged in the first direction DR1. The selection circuits SC may selectively connect the data lines DL1 to DLn to the odd-numbered pixels PX and the even-numbered pixels PX. This configuration will be described in detail below.

The timing controller T-CON may receive image signals RGB and a control signal CS from the outside (e.g., a system board). The timing controller T-CON may generate image data DATA by converting a data format of the image signals RGB according to an interface specification between the data driver DDV and the timing controller T-CON. The timing controller T-CON may provide the data driver DDV with the image data DATA having the converted data format.

The timing controller T-CON may generate and output a first control signal CS1, a second control signal CS2, a third control signal CS3, and first and second switching control signals SS1 and SS2 in response to the control signal CS provided from the outside. The first control signal CS1 may be defined as a scan control signal, the second control signal CS2 may be defined as a data control signal, and the third control signal CS3 may be defined as an emission control signal.

The first control signal CS1 may be provided to the scan driver SDV, the second control signal CS2 may be provided to the data driver DDV, and the third control signal CS3 may be provided to the emission driver EDV. The first and second switching control signals SS1 and SS2 may be provided to the selection circuits SC.

The scan driver SDV may generate a plurality of scan signals in response to the first control signal CS1. The scan signals may be applied to the pixels PX through the scan lines SL1 to SLm.

The data driver DDV may generate a plurality of data voltages corresponding to the image data DATA in response to the second control signal CS2. The data voltages may be applied to the pixels PX through the data lines DL1 to DLn and the selection circuits SC.

The selection circuits SC may selectively connect the data lines DL1 to DLn to the odd-numbered pixels PX and the even-numbered pixels PX, in response to the first and second switching control signals SS1 and SS2. For example, the selection circuits SC may connect the data lines DL1 to DLn to the odd-numbered pixels PX in response to the first switching control signal SS1. The selection circuits SC may connect the data lines DL1 to DLn to the even-numbered pixels PX in response to the second switching control signal SS2. This operation will be described in detail below.

The emission driver EDV may generate a plurality of emission signals in response to the third control signal CS3. The emission signals may be applied to the pixels PX through the emission lines EL1 to ELm.

The pixels PX may receive the data voltages in response to the scan signals. The pixels PX may display an image by emitting light of luminance corresponding to the data voltages in response to the emission signals. The emission time of the pixels PX may be controlled by the emission signals.

FIG. 5 is a plan view of the display panel illustrated in FIG. 4.

When descriptions are given hereinafter with reference to FIG. 5, descriptions overlapping with those given with reference to FIG. 4 will not be given.

Referring to FIG. 5, the display panel DP may include a display area DA and a non-display area NDA surrounding the display area DA. The display panel DP may have a rectangular shape having long sides extending in the first direction DR1 and short sides extending in the second direction DR2, but the shape of the display panel DP is not limited thereto.

The pixels PX and the selection circuits SC may be disposed in the display area DA. The scan driver SDV and the emission driver EDV may be disposed in portions of the non-display area NDA respectively adjacent to the long sides of the display panel DP.

The display panel DP may include a plurality of first selection lines SSL1 and a plurality of second selection lines SSL2. The selection circuits SC may be connected to the first selection lines SSL1 and the second selection lines SSL2. The first selection lines SSL1 and the second selection lines SSL2 may extend in the same direction as the data lines DL1 to DLn. For example, the first selection lines SSL1 and the second selection lines SSL2 may extend in the first direction DR1.

The pixels PX may include a plurality of first pixels PX1 and a plurality of second pixels PX2 adjacent to the first pixels PX1. Four pairs of first and second pixels PX1 and PX2 are illustrated as an example, but more pixels PX may be disposed in the display panel DP.

The first pixels PX1 and the second pixels PX2 may be alternately disposed in the second direction DR2. The first pixels PX1 may be arranged in the first direction DR1. The second pixels PX2 may be arranged in the first direction DR1.

The second direction DR2 may correspond to a row direction, and the first direction DR1 may correspond to a column direction. The first pixels PX1 may be defined as the above-described odd-numbered pixels PX, and the second pixels PX2 may be defined as the above-described even-numbered pixels PX. For example, in a k-th row, each of odd-numbered pixels PX may be defined as one of the first pixels PX1, and each of even-numbered pixels PX may be defined as one of the second pixels PX2. Here, k is a natural number.

Each of the selection circuits SC may be disposed between a pair of a first pixel PX1 and a second pixel PX2 adjacent to each other and connected to the pair of the first pixel PX1 and the second pixel PX2 adjacent to each other. Corresponding ones of the selection circuits SC disposed in each column may be connected to a corresponding data line of the data lines DL1 to DLn. For example, corresponding ones of the selection circuits SC disposed in an l-th column may be connected to a corresponding one of the data lines DL1 to DLn. Here, I is a natural number.

The selection circuits SC may selectively connect the data lines DL1 to DLn to the first pixels PX1 and the second pixels PX2. For example, each of the selection circuits SC may alternately connect a corresponding one of the data lines to a pair of a first pixel PX1 and a second pixel PX2. This configuration will be described in detail below.

The display device DD may include a flexible circuit board FPCB and a printed circuit board PCB, without limitation thereto. One side of the flexible circuit board FPCB may be connected to the display panel DP, and the other side thereof may be connected to the printed circuit board PCB.

The data driver DDV may be disposed on the flexible circuit board FPCB. The timing controller T-CON may be disposed on the printed circuit board PCB. The data driver DDV may be manufactured in the form of an integrated circuit chip to be mounted on the flexible circuit board FPCB. The timing controller T-CON may be manufactured in the form of an integrated circuit chip to be mounted on the printed circuit board PCB.

The data driver DDV may be connected to the data lines DL1 to DLn through the flexible circuit board FPCB. For example, lines (reference numerals thereof not illustrated) disposed in the flexible circuit board FPCB and connected to the data driver DDV may be connected to the data lines DL1 to DLn.

The data driver DDV may be connected to the timing controller T-CON through the flexible circuit board FPCB. For example, lines (reference numerals thereof not illustrated) connecting the timing controller T-CON and the data driver DDV may extend from the flexible circuit board FPCB to the printed circuit board PCB.

The display device DD may include a first control line CL1, a second control line CL2, a first signal line L1, and a second signal line L2. The first control line CL1 may be connected to the timing controller T-CON and may be connected to the scan driver SDV via the flexible circuit board FPCB. The second control line CL2 may be connected to the timing controller T-CON and may be connected to the emission driver EDV via the flexible circuit board FPCB.

The first control line CL1 may receive the above-described first control signal CS1, and the second control line CL2 may receive the above-described third control signal CS3. The second control signal CS2 may be provided to the data driver DDV through lines connecting the timing controller T-CON and the data driver DDV.

The first signal line L1 and the second signal line L2 may be connected to the timing controller T-CON and may extend to the display area DA via the flexible circuit board FPCB. The first selection lines SSL1 may be connected to the first signal line L1 in common. The second selection lines SSL2 may be connected to the second signal line L2 in common.

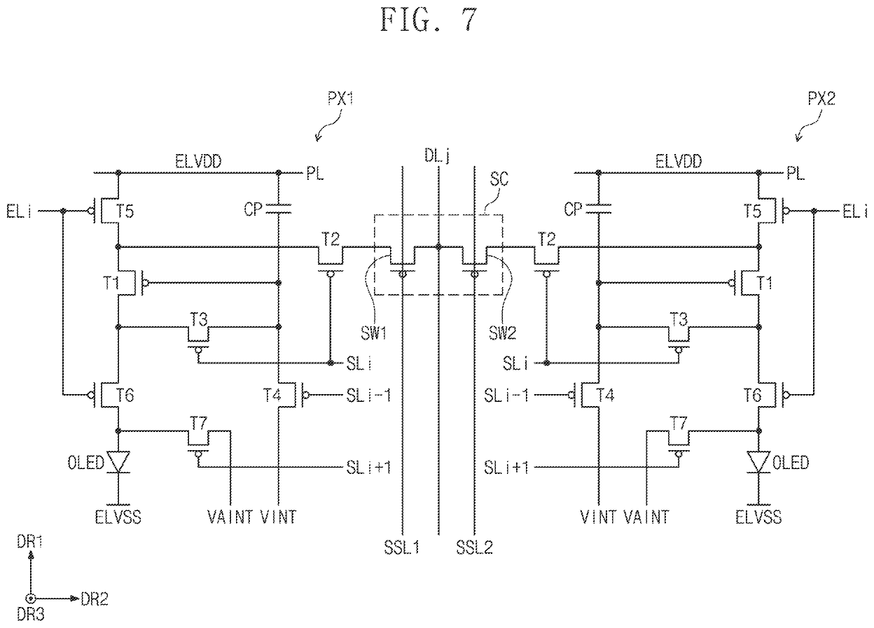

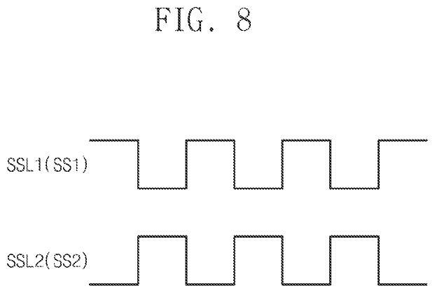

Referring to FIGS. 4 and 5, the timing controller T-CON may generate the first switching control signal SS1 and the second switching control signal SS2 described above. An operation of the display device DD according to the first and second switching control signals SS1 and SS2 will be described in detail below with reference to FIGS. 7 and 8.

The first switching control signal SS1 may be output through the first signal line L1, and the second switching control signal SS2 may be output through the second signal line L2. The first switching control signal SS1 may be applied to the first selection lines SSL1 through the first signal line L1, and the second switching control signal SS2 may be applied to the second selection lines SSL2 through the second signal line L2.

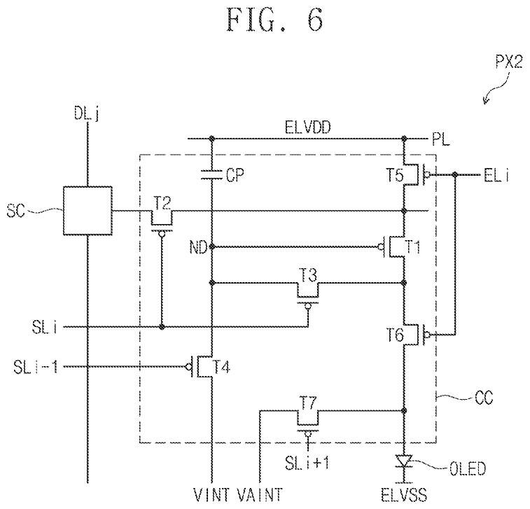

FIG. 6 illustrates, as an example, an equivalent circuit of any one of the second pixels illustrated in FIG. 5.

Although a configuration of any one of the second pixels PX2 is illustrated as an example, other first and second pixels may also have substantially the configuration illustrated in FIG. 6.

Referring to FIG. 6, the second pixel PX2 may include a light emitting element OLED and a pixel circuit CC. The second pixel PX2 connected to an i-th scan line SLi, an i-th emission line ELi, and a j-th data line DLj is illustrated as an example in FIG. 6. The second pixel PX2 may be connected to the j-th data line DLj through a corresponding one of the selection circuits SC. Hereinafter, the second pixel PX2 will be described, assuming that the j-th data line DLj is connected to the second pixel PX2.

The pixel circuit CC may include a plurality of transistors T1 to T7 and a capacitor CP. The pixel circuit CC may control an amount of a current flowing to the light emitting element OLED. The light emitting element OLED may generate light having luminance corresponding to the amount of the current supplied from the pixel circuit CC.

The transistors T1 to T7 may each include an input electrode (or a source electrode), an output electrode (or a drain electrode), and a control electrode (or a gate electrode). In the present disclosure, for convenience, one of the input electrode and the output electrode may be referred to as a first electrode, and the other thereof may be referred to as a second electrode.

A first electrode of a first transistor T1 may receive a first voltage ELVDD via a fifth transistor T5, and a second electrode of the first transistor T1 may be connected to an anode of the light emitting element OLED via a sixth transistor T6. A cathode of the light emitting element OLED may receive a second voltage ELVSS having a level lower than that of the first voltage ELVDD.

The first transistor T1 may be defined as a driving transistor. The control electrode of the first transistor T1 may be connected to a node ND. The first transistor T1 may control the amount of the current flowing to the light emitting element OLED according to a voltage applied to the control electrode of the first transistor T1.

A second transistor T2 may be connected between the data line DLj and the first electrode of the first transistor T1, and the control electrode of the second transistor T2 may be connected to the i-th scan line SLi. A first electrode of the second transistor T2 may be connected to the data line DLj, and a second electrode of the second transistor T2 may be connected to the first electrode of the first transistor T1. The second transistor T2 may be turned on by receiving an i-th scan signal through the i-th scan line SLi to electrically connect the data line DLj and the first electrode of the first transistor T1.

A third transistor T3 may be connected between the second electrode of the first transistor T1 and the control electrode of the first transistor T1. The control electrode of the third transistor T3 may be connected to the i-th scan line SLi. The third transistor T3 may be turned on by receiving the i-th scan signal through the i-th scan line SLi to electrically connect the second electrode of the first transistor T1 and the control electrode of the first transistor T1. The first transistor T1 may be connected in the form of a diode when the third transistor T3 is turned on.

A fourth transistor T4 may be connected between the node ND and an initialization power generating unit (not illustrated). The control electrode of the fourth transistor T4 may be connected to an (i−1)-th scan line SLi−1. The fourth transistor T4 may be turned on by receiving an (i−1)-th scan signal through the (i−1)-th scan line SLi−1 to provide a first initialization voltage VINT to the node ND.

The fifth transistor T5 may be connected between a power line PL and the first electrode of the first transistor T1. The power line PL may receive the first voltage ELVDD. The control electrode of the fifth transistor T5 may be connected to the i-th emission line ELi.

The sixth transistor T6 may be connected between the second electrode of the first transistor T1 and the anode of the light emitting element OLED. The control electrode of the sixth transistor T6 may be connected to the i-th emission line ELi.

A seventh transistor T7 may be connected between an initialization power generating unit (not illustrated) and the anode of the light emitting element OLED. The control electrode of the seventh transistor T7 may be connected to an (i+1)-th scan line SLi+1. The seventh transistor T7 may be turned on by receiving an (i+1)-th scan signal through the (i+1)-th scan line SLi+1 to provide a second initialization voltage VAINT to the anode of the light emitting element OLED. The second initialization voltage VAINT may have a level different from or the same as that of the first initialization voltage VINT.

The capacitor CP may be disposed between the power line PL and the node ND. The capacitor CP may store a corresponding one of the data voltages. When the fifth transistor T5 and the sixth transistor T6 are turned on, the amount of a current flowing through the first transistor T1 may be determined depending on the voltage stored in the capacitor CP.

Although the transistors T1 to T7 may include PMOS transistors, the transistors T1 to T7 are not limited thereto and may include NMOS transistors in an embodiment of the present disclosure.

FIG. 7 illustrates, as an example, equivalent circuits of one of the first pixels PX1 and one of the second pixels PX2 adjacent to each other and a corresponding one of the selection circuits SC illustrated in FIG. 5. FIG. 8 is a timing diagram of first and second switching control signals applied to the first and second switching elements illustrated in FIG. 7.

Referring to FIGS. 7 and 8, the first pixel PX1 and the second pixel PX2 may have substantially the same structures. However, the structures of the first pixel PX1 and the second pixel PX2 may be symmetric to each other. For example, the first pixel PX1 may include the plurality of transistors T1 to T7, the capacitor CP, and the light emitting element OLED. The transistors T1 to T7, the capacitor CP, and the light emitting element OLED of the first pixel PX1 may be disposed to be symmetric to the transistors T1 to T7, the capacitor CP, and the light emitting element OLED of the second pixel PX2.

The selection circuit SC may be connected to the first pixel PX1, the second pixel PX2, the data line DLj, a corresponding one of the first selection lines SSL1, and a corresponding one of the second selection lines SSL2. Although not illustrated, the first selection line SSL1 and the second selection line SSL2 may further extend in the first direction DR1 to be further connected to selection circuits SC disposed in the same column as the selection circuit SC illustrated in FIG. 7. In addition, the data line DLj may further extend in the first direction DR1 to be further connected to the selection circuits SC disposed in the same column as the selection circuit SC illustrated in FIG. 7.

The selection circuit SC may be connected to the second transistor T2 of the first pixel PX1. The selection circuit SC may be connected to the second transistor T2 of the second pixel PX2.

The selection circuit SC may include a first switching element SW1 for switching a connection between the data line DLj and the first pixel PX1 and a second switching element SW2 for switching a connection between the data line DLj and the second pixel PX2. Although the first and second switching elements SW1 and SW2 may include PMOS transistors, the first and second switching elements SW1 and SW2 are not limited thereto and may also include NMOS transistors.

The first switching element SW1 may be connected to the second transistor T2 of the first pixel PX1. The second switching element SW2 may be connected to the second transistor T2 of the second pixel PX2. The first and second switching elements SW1 and SW2 may be respectively connected to the first electrodes of the second transistors T2 of the first and second pixels PX1 and PX2.

The data line DLj may be disposed between the first switching element SW1 and the second switching element SW2 to be connected to the first switching element SW1 and the second switching element SW2. The first switching element SW1 may be disposed between the data line DLj and the first pixel PX1 to be connected to the data line DLj and the first pixel PX1. The second switching element SW2 may be disposed between the data line DLj and the second pixel PX2 to be connected to the data line DLj and the second pixel PX2.

The first switching element SW1 may be connected to the first selection line SSL1 and may be controlled to be turned on/off by the first switching control signal SS1 applied through the first selection line SSL1. The second switching element SW2 may be connected to the second selection line SSL2 and may be controlled to be turned on/off by the second switching control signal SS2 applied through the second selection line SSL2.

The first switching control signal SS1 may be an inverted signal of the second switching control signal SS2. Accordingly, the first switching element SW1 and the second switching element SW2 may be alternately turned on. The first switching element SW1 may be turned on in response to a first switching control signal SS1 of a low level. The second switching element SW2 may be turned on in response to a second switching control signal SS2 of the low level.

The first pixel PX1 and the second pixel PX2 may be alternately connected to the data line DLj by the first switching element SW1 and the second switching element SW2 that are alternately turned on. As a result, the selection circuit SC may alternately connect the data line DLj to the first pixel PX1 and the second pixel PX2.

Because the first pixel PX1 and the second pixel PX2 are alternately connected to the data line DLj, the first pixel PX1 and the second pixel PX2 may alternately receive the data voltage. Accordingly, the first pixel PX1 and the second pixel PX2 may be driven alternately.

Although not illustrated, the first selection line SSL1 and the second selection line SSL2 may further extend in the first direction DR1 to be connected to first and second switching elements SW1 and SW2 of the selection circuits SC disposed in the same column as the selection circuit SC illustrated in FIG. 7.

Hereinafter, any one of an input electrode (e.g., a source electrode) and an output electrode (e.g., a drain electrode) of each of the first and second switching elements SW1 and SW2 is referred to as a first electrode, and the other thereof is referred to as a second electrode. In addition, a gate electrode of each of the first and second switching elements SW1 and SW2 is referred to as a control electrode.

The first switching element SW1 may include a first electrode connected to the data line DLj, a second electrode connected to the first pixel PX1, and the control electrode connected to the first selection line SSL1. The second electrode of the first switching element SW1 may be connected to the first electrode of the second transistor T2 of the first pixel PX1.

The first switching control signal SS1 may be applied to the control electrode of the first switching element SW1 through the first selection line SSL1. The first switching element SW1 may be turned on by the first switching control signal SS1 applied to the control electrode of the first switching element SW1. The data line DLj may be connected to the second transistor T2 of the first pixel PX1 by the turned-on first switching element SW1.

The second switching element SW2 may include a first electrode connected to the data line DLj, a second electrode connected to the second pixel PX2, and the control electrode connected to the second selection line SSL2. The second electrode of the second switching element SW2 may be connected to the first electrode of the second transistor T2 of the second pixel PX2.

The second switching control signal SS2 may be applied to the control electrode of the second switching element SW2 through the second selection line SSL2. The second switching element SW2 may be turned on by the second switching control signal SS2 applied to the control electrode of the second switching element SW2. The data line DLj may be connected to the second transistor T2 of the second pixel PX2 by the turned-on second switching element SW2.

In an embodiment of the present disclosure, the first pixel PX1 and the second pixel PX2 need not be connected to two data lines, respectively, but may be connected to one data line DLj in common. Accordingly, the number of the data lines may be reduced.

Referring to FIGS. 5 and 7, a portion of the non-display area NDA between the data driver DDV and the display area DA may be defined as a fan-out portion F-O. The lines may extend radially in the fan-out portion F-O. When the selection circuits SC are disposed in the fan-out portion F-O, a surface area of the fan-out portion F-O may increase.

However, in an embodiment of the present disclosure, the selection circuits SC for alternately driving the first pixels PX1 and the second pixels PX2 may be disposed in the display area DA. Accordingly, the surface area of the fan-out portion F-O may be reduced.

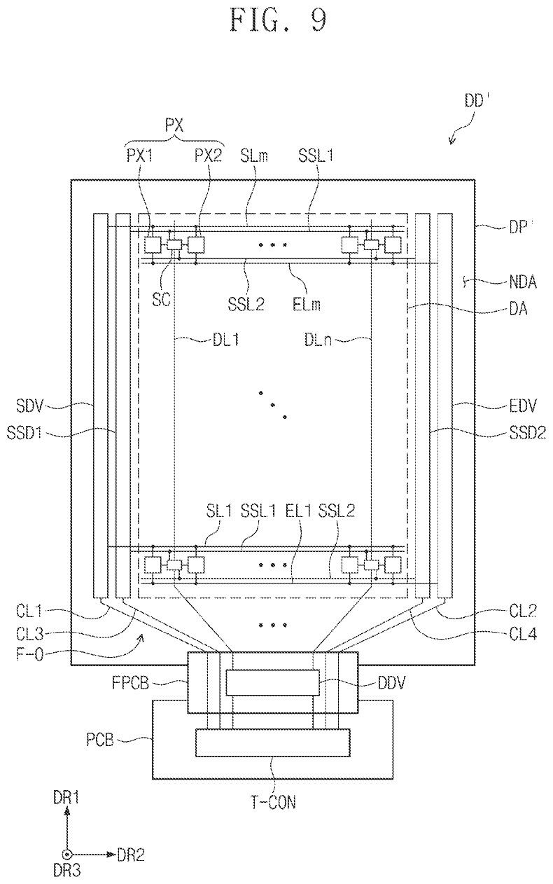

FIG. 9 is a plan view of a display panel according to an embodiment of the present disclosure.

Hereinafter, components of a display panel DP′ illustrated in FIG. 9 will be described, focusing on components different from the components illustrated in FIG. 5.

Referring to FIG. 9, a display device DD′ may include a first selection driver SSD1, a second selection driver SSD2, and third and fourth control lines CL3 and CL4. The first selection driver SSD1 may be disposed between a display area DA and a scan driver SDV. The second selection driver SSD2 may be disposed between the display area DA and an emission driver EDV.

The third control line CL3 may be connected to a timing controller T-CON and may be connected to the first selection driver SSD1 via a flexible circuit board FPCB. The fourth control line CL4 may be connected to the timing controller T-CON and may be connected to the second selection driver SSD2 via the flexible circuit board FPCB.

First selection lines SSL1 may extend in a second direction DR2 and may be arranged in a first direction DR1. The first selection lines SSL1 may be connected to the first selection driver SSD1. Second selection lines SSL2 may extend in the second direction DR2 and may be arranged in the first direction DR1. The second selection lines SSL2 may be connected to the second selection driver SSD2.

The first and second selection lines SSL1 and SSL2 may extend to cross data lines DL1 to DLn. The first and second selection lines SSL1 and SSL2 may be insulated from the data lines DL1 to DLn.

The first selection lines SSL1 and the second selection lines SSL2 may be connected to selection circuits SC. As the configuration illustrated in FIG. 7, the first selection lines SSL1 may be connected to first switching elements SW1 of the selection circuits SC, and the second selection lines SSL2 may be connected to second switching elements SW2 of the selection circuits SC.

The first selection lines SSL1 and the second selection lines SSL2 may be connected row by row to the selection circuits SC. For example, selection circuits SC disposed in an h-th row may be connected to an h-th first selection line SSL1 and an h-th second selection line SSL2 among the first and second selection lines SSL1 and SSL2. Here, h is a natural number.

Although the illustrative embodiment of FIG. 7 shows the first and second switching elements SW1 and SW2 of substantially the same type (e.g., both PMOS) connected to separate selection lines SSL1 and SSL2, respectively, embodiments of the present disclosure are not limited thereto. For example, in an alternate embodiment, the first and second selection lines SSL1 and SSL2 may be replaced by a single selection line SSL connected to first and second switching elements of substantially complimentary symmetrical types (e.g., one of PMOS and the other of NMOS) or the like to further reduce a quantity of signal lines within a display panel.

In another example where the first and second switching elements SW1 and SW2 do have substantially the same type, an inverter may be connected to the gate terminal of one or the other of the switching elements to reduce the number of selection lines. Here, appropriate timing adjustments may be made in the timing controller, for example, to compensate for any additional delay of the inverter. That is, the selection signal need not be symmetric in this example.

The timing controller T-CON may generate a fourth control signal, and the fourth control signal may be provided to the first selection driver SSD1 through the third control line CL3. The timing controller T-CON may generate a fifth control signal, and the fifth control signal may be provided to the second selection driver SSD2 through the fourth control line CL4.

The first selection driver SSD1 may generate a first switching control signal SS1 as described above, in response to the fourth control signal. The second selection driver SSD2 may generate a second switching control signal SS2 as described above, in response to the fifth control signal.

The first selection driver SSD1 may output the first switching control signal SS1 through the first selection lines SSL1. The second selection driver SSD2 may output the second switching control signal SS2 through the second selection lines SSL2. As described above (illustrated in FIGS. 7 and 8), the first and second switching elements SW1 and SW2 may be alternately turned on by the first and second switching control signals SS1 and SS2.

In the case that the first and second selection drivers SSD1 and SSD2 are disposed adjacent to the display area DA to generate the first and second switching control signals SS1 and SS2, the first and second switching control signals SS1 and SS2 may be applied to the selection circuits SC more stably.

According to an embodiment of the present disclosure, because one data line is connected to a pair of first and second pixels, and the selection circuits a corresponding one of which selectively drives the first and second pixels are disposed in the display area, the number of the data lines and the surface area of the fan-out portion may be reduced.

Although illustrative embodiments of the present disclosure have been described herein by way of example, it shall be understood that various changes and modifications can be made by those of ordinary skill in the pertinent art without departing from the spirit and scope of the present disclosure as defined by the following claims or equivalents thereof. The illustrative embodiments described herein are not intended to limit the technical spirit or scope of the present disclosure, and all technical aspects falling within the scope of the following claims or their equivalents shall be construed as being included within the scope of the present disclosure.

What is claimed is:

1. A display device comprising:
a first pixel;
a second pixel adjacent to the first pixel;
a selection circuit disposed between the first pixel and the second pixel; and
a data line connected to the selection circuit,
wherein the selection circuit selectively connects the data line to at least one of the first pixel and the second pixel.

2. The display device of claim 1, wherein the selection circuit alternately connects the data line to one of the first pixel and the second pixel and then to the other of the first pixel and the second pixel.

3. The display device of claim 1, wherein the first pixel and the second pixel have structures symmetric to each other.

4. The display device of claim 1, wherein the selection circuit comprises:
a first switching element configured to switch a connection between the data line and the first pixel; and
a second switching element configured to switch a connection between the data line and the second pixel.

5. The display device of claim 4, wherein the data line is disposed between the first switching element and the second switching element to be connected to the first switching element and the second switching element.

6. The display device of claim 4, wherein the first switching element is disposed between the data line and the first pixel to be connected to the data line and the first pixel.

7. The display device of claim 4, wherein the second switching element is disposed between the data line and the second pixel to be connected to the data line and the second pixel.

8. The display device of claim 4, wherein the first and second switching elements comprise PMOS transistors.

9. The display device of claim 4, further comprising:
a first selection line connected to the first switching element and configured to receive a first switching control signal to control on/off states of the first switching element; and
a second selection line connected to the second switching element and configured to receive a second switching control signal to control on/off states of the second switching element.

10. The display device of claim 9, wherein the data line, the first selection line, and the second selection line extend in the same direction.

11. The display device of claim 9, wherein the first switching control signal is an inverted signal of the second switching control signal.

12. The display device of claim 9, wherein the first switching element comprises:
a first electrode connected to the data line;
a second electrode connected to the first pixel; and
a control electrode connected to the first selection line.

13. The display device of claim 9, wherein the second switching element comprises:
a first electrode connected to the data line;
a second electrode connected to the second pixel; and
a control electrode connected to the second selection line.

14. The display device of claim 9, further comprising:
a timing controller configured to generate the first and second switching control signals;
a first signal line connected to the timing controller to output the first switching control signal; and
a second signal line connected to the timing controller to output the second switching control signal.

15. The display device of claim 14, wherein each of the first and second pixels, the data line, the first selection line, and the second selection line is provided in plurality,
wherein the plurality of first selection lines are connected in common to the first signal line.

16. The display device of claim 15, wherein the plurality of second selection lines are connected in common to the second signal line.

17. The display device of claim 9, wherein
each of the first and second pixels, the data line, the first selection line, and the second selection line is provided in plurality,
the plurality of data lines extend in a first direction, and the plurality of first selection lines and the plurality of second selection lines extend in a second direction crossing the first direction, and
an h-th first selection line and an h-th second selection line among the first and second selection lines are connected to selection circuits disposed in an h-th row, the row corresponds to the second direction, and h is a natural number.

18. The display device of claim 17, further comprising:
a first selection driver connected to the plurality of first selection lines and configured to output the first switching control signal; and
a second selection driver connected to the plurality of second selection lines and configured to output the second switching control signal.

19. A display device comprising:
a first pixel;
a second pixel adjacent to the first pixel;
a data line disposed between the first pixel and the second pixel and configured to be connected to the first pixel and the second pixel;
a first switching element disposed between the first pixel and the data line and configured to be connected to the first pixel and the data line; and
a second switching element disposed between the second pixel and the data line and configured to be connected to the second pixel and the data line,
wherein the first switching element and the second switching element are alternately turned on.

20. The display device of claim 19, further comprising:
a first selection line connected to the first switching element and configured to receive a first switching control signal to control on/off states of the first switching element; and
a second selection line connected to the second switching element and configured to receive a second switching control signal to control on/off states of the second switching element.
